(19) United States
(12) Patent Application Publication
(10) Pub. No.: US 2026/0240008 A1
(43) Pub. Date: Aug. 13, 2026

(54) ELECTRONIC DEVICE

(71) Applicant: InnoLux Corporation, Miao-Li County (TW)

(72) Inventors: Kuan-Feng LEE, MIao-Li County (TW); Tsung-Han TSAI, Miao-Li County (TW); Jui-Jen YUEH, Miao-Li County (TW); Wen-Bin HUNG, Miao- Li County (TW)

(73) Assignee: InnoLux Corporation, Miao-Li County (TW)

(21) Appl. No.: 19/446,955

(22) Filed: Jan. 13, 2026

(30) Foreign Application Priority Data
Feb. 10, 2025 (CN) 202510142595.2

(51) Int. Cl. H10W 70/60; H10W 70/63; H10W 72/00; H10W 74/10; H10W 90/00; H10W 90/22

(52) U.S. Cl. CPC H10W 70/618; H10W 70/63; H10W 72/812; H10W 74/117; H10W 74/124; H10W 90/22; H10W 90/724; H10W 90/794

(57) ABSTRACT

An electronic device includes a substrate, a first electronic element and a connection layer. The substrate includes a first surface and a second surface opposite to the first surface, wherein the first surface has a cavity, and a bottom of the cavity includes a plurality of first concaves. The first electronic element is disposed in the cavity. The connection layer is disposed in the cavity and contacts the first electronic element. At least a portion of the connection layer is disposed between the plurality of first concaves and the first electronic element.

### BACKGROUND OF THE DISCLOSURE

### 1. Field of the Disclosure

The present disclosure relates to an electronic device, and more particularly to an electronic device whose substrate has a cavity.

### 2. Description of the Prior Art

In current electronic devices, the substrate may include a cavity to accommodate the electronic element. However, the connection between the electronic element in the cavity and the substrate may be poor. Therefore, to reduce the above-mentioned problem is still an important issue in the present field.

### SUMMARY OF THE DISCLOSURE

An electronic device is provided by the present disclosure. The electronic device includes a substrate, a first electronic element and a connection layer. The substrate includes a first surface and a second surface opposite to the first surface, wherein the first surface has a cavity, and a bottom of the cavity includes a plurality of first concaves. The first electronic element is disposed in the cavity. The connection layer is disposed in the cavity and contacts the first electronic element. At least a portion of the connection layer is disposed between the plurality of first concaves and the first electronic element.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 schematically illustrates a cross-sectional view of an electronic device of a first embodiment of the present disclosure.

FIG. 2 schematically illustrates a top view of the substrate of the electronic device of the first embodiment of the present disclosure.

FIG. 3 schematically illustrates a cross-sectional view of an electronic device of a second embodiment of the present disclosure.

FIG. 4 schematically illustrates a top view of an electronic device of a third embodiment of the present disclosure.

FIG. 5 schematically illustrates a cross-sectional view of an electronic device of a fourth embodiment of the present disclosure.

FIG. 6 schematically illustrates a cross-sectional view of an electronic device of a fifth embodiment of the present disclosure.

FIG. 7 schematically illustrates a cross-sectional view of an electronic device of a sixth embodiment of the present disclosure.

FIG. 8 schematically illustrates a cross-sectional view of an electronic device of a seventh embodiment of the present disclosure.

FIG. 9 schematically illustrates a cross-sectional view of an electronic device of an eighth embodiment of the present disclosure.

FIG. 10 schematically illustrates a top view of an electronic device of a ninth embodiment of the present disclosure.

FIG. 11 schematically illustrates a top view of an electronic device of a tenth embodiment of the present disclosure.

FIG. 12 schematically illustrates a cross-sectional view of an electronic device of an eleventh embodiment of the present disclosure.

FIG. 13 schematically illustrates a cross-sectional view of an electronic device of a variant embodiment of the eleventh embodiment of the present disclosure.

FIG. 14 schematically illustrates a cross-sectional view of an electronic device of a twelfth embodiment of the present disclosure.

FIG. 15 schematically illustrates a cross-sectional view of an electronic device of a thirteenth embodiment of the present disclosure.

FIG. 16 shows examples of top views of the cavity and the first concaves in the electronic device of the present disclosure.

### DETAILED DESCRIPTION

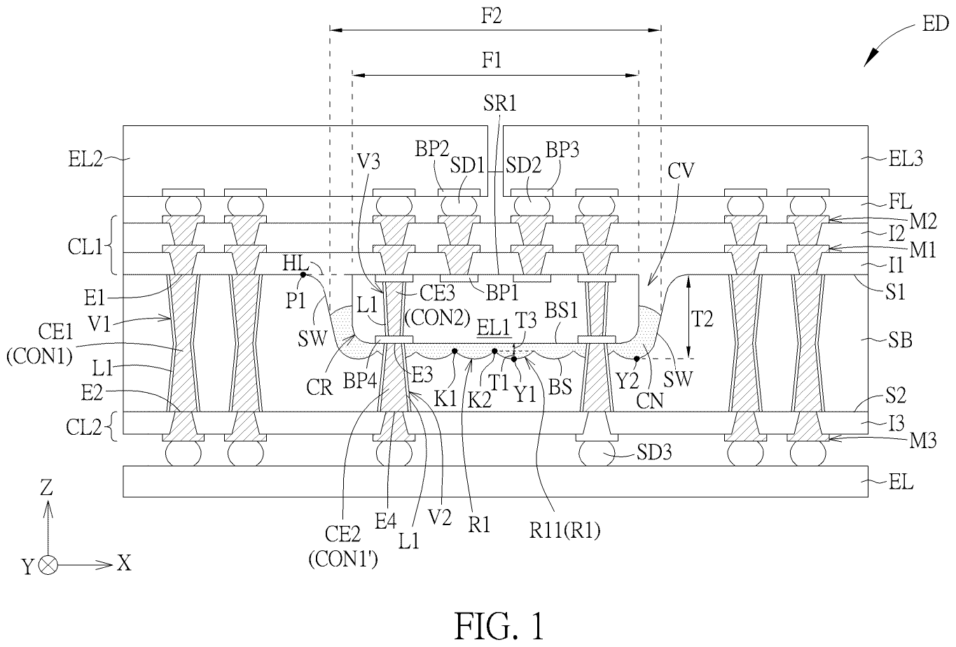

As shown in FIG. 1, the electronic device ED includes a substrate SB. The substrate SB includes a first surface S1 and a second surface S2 opposite to the first surface S1. The first surface S1 of the substrate SB has a cavity CV. The cavity CV may not penetrate the substrate SB. In such condition, the cavity CV may have a sidewall SW, wherein the sidewall SW may be connected to the first surface S1 but not connected to the second surface S2. The sidewall SW of the cavity CV may also be regarded as an inner surface of the substrate SB. The upper end of the sidewall SW may correspond to a point P1 on the surface of the substrate SB that begins to deviate from a virtual line HL parallel to the first surface S1 of the substrate SB (or parallel to the direction X or direction Y). In addition, the cavity CV may have a bottom surface BS, wherein the bottom surface BS may be a surface of a portion of the substrate SB exposed by the cavity CV. It should be noted the first surface S1 of the electronic device ED may include cavities CV.

As shown in FIG. 1, the electronic device ED further includes a first electronic element EL1 disposed in the cavity CV. The first electronic element EL1 includes a surface SR1 opposite to the bottom surface BS of the cavity CV, wherein the surface SR1 may be substantially aligned with the first surface S1. In this embodiment, one first electronic element EL1 may be disposed in one cavity CV. The electronic device ED includes first electronic elements EL1 and cavities CV, and the first electronic elements EL1 may be respectively disposed in the cavities CV. In some embodiments, the first electronic elements EL1 may be disposed in one cavity CV. The electronic device ED further includes a connection layer CN, wherein the connection layer CN is disposed in the cavity CV and contacts the first electronic element EL1. The connection layer CN may be used to connect the first electronic element EL1 and the cavity CV or to fix the first electronic element EL1 in the cavity CV. The connection layer CN may be disposed at least between the first electronic element EL1 and the bottom surface BS of the cavity CV. The connection layer CN may be partially located between the first electronic element EL1 and the sidewall SW of the cavity CV. The connection layer CN includes any suitable adhesive material.

In a cross-sectional view of the electronic device ED, the bottom of the first electronic element EL1 may have a curved corner or other suitable non-sharp corners. For example, the bottom of the first electronic element EL1 may have a corner CR, wherein the corner CR includes an arc shape or other suitable non-sharp shapes. In a cross-sectional view of the electronic device ED, the first electronic element EL1 may have a width F1, and the connection layer CN may have a width F2, wherein the width F2 may be greater than or equal to 50% of the width F1. The width F1 of the first electronic element EL1 may be defined as the maximum width of the first electronic element EL1 in a direction perpendicular to the normal direction of the electronic device ED (such as the direction X), and the width F2 of the connection layer CN may be defined as the maximum width of the connection layer CN in the direction. In some embodiments, the width F2 may be the same as the width F1. In some embodiments, the width F2 may be 1.1 times the width F1.

The bottom of the cavity CV includes first concaves R1. Specifically, the manufacturing process of the electronic device ED further includes removing a portion of the substrate SB from the bottom surface BS of the cavity CV to form the first concaves R1. The cavity CV and the first concaves R1 may be formed through the same process. In some embodiments, the cavity CV and the first concaves R1 may be formed by multiple processes. The first concaves R1 and the cavity CV may for example be formed by performing a modification process and an etching process on the substrate SB. In a cross-sectional view of the electronic device ED, the bottom surface BS of the cavity CV may be a wavy surface. In such condition, a first concave R1 may correspond to a portion of the bottom surface BS of the cavity CV between two adjacent peaks (such as the peak K1 and the peak K2). In this embodiment, at least a portion of the connection layer CN may be disposed in the first concaves R1. In detail, a portion of the connection layer CN is filled in at least one first concave R1. In addition, the connection layer CN is completely or partially filled into the first concaves R1. In such condition, at least a portion of the connection layer CN is disposed between the first concaves R1 and the first electronic element EL1.

One of the first concaves R1 may have a depth T1, wherein the depth T1 may be the maximum depth of the first concave R1 in a normal direction of the electronic device ED. The depth T1 may be defined as the distance between a peak and a valley which are adjacent to each other on the bottom surface BS of the cavity CV in the normal direction (the direction Z) of the electronic device ED. For example, the distance between a peak K2 and a valley Y1 on the bottom surface BS in the normal direction of the electronic device ED may be defined as the depth T1. It should be noted that the depths T1 of different first concaves R1 may be the same or different. The depth T1 of the first concave R1 may range from 0.5 micrometers (μm) to 20 μm (0.5 μm≤T1≤20 μm). In some embodiments, the depth T1 may range from 0.5 μm to 10 μm (0.5 μm≤T1≤10 μm). In some embodiments, the depth T1 may range from 1 μm to 5 μm (1 μm≤T1≤5 μm).

The cavity CV may have a depth T2, wherein the depth T2 may be defined as a distance between the first surface S1 of the substrate SB and a valley closest to the sidewall SW on the bottom surface BS in the normal direction to the electronic device ED. For example, on the right side of the cavity CV, the distance between the first surface S1 and the valley Y2 on the bottom surface BS in the normal direction of the electronic device ED may be defined as the depth T2. A ratio of the depth T1 to the depth T2 may range from 0.01 to 0.25 (0.01≤T1/T2≤0.25). In some embodiments, T1/T2 may range from 0.05 to 0.15(0.05 ≤T1/T2≤0.15).

A distance T3 may be included between the bottom of the first electronic element EL1 and the bottom of one of the first concaves R1. The distance T3 may be defined as the distance between the bottom surface BS1 of the first electronic element EL1 and the bottom of a first concave R1 (or one of the valleys of the bottom surface BS) in the normal direction of the electronic device ED. The distance T3 may be greater than or equal to the depth T1. For example, the distance T3 may be included between the bottom of the first electronic element EL1 and the bottom of the first concave R11 (the valley Y1), wherein the distance T3 may be greater than or equal to the depth T1 of the first concave R11. In other words, the comparison between the distance T3 and the depth T1 mentioned above is performed when the distance T3 and the depth T1 are measured on the same measurement line. When the distance T3 is equal to the depth T1, the first electronic element EL1 may contact the peak of the bottom surface BS. When the distance T3 is greater than the depth T1, the first electronic element EL1 may not contact the bottom surface BS.

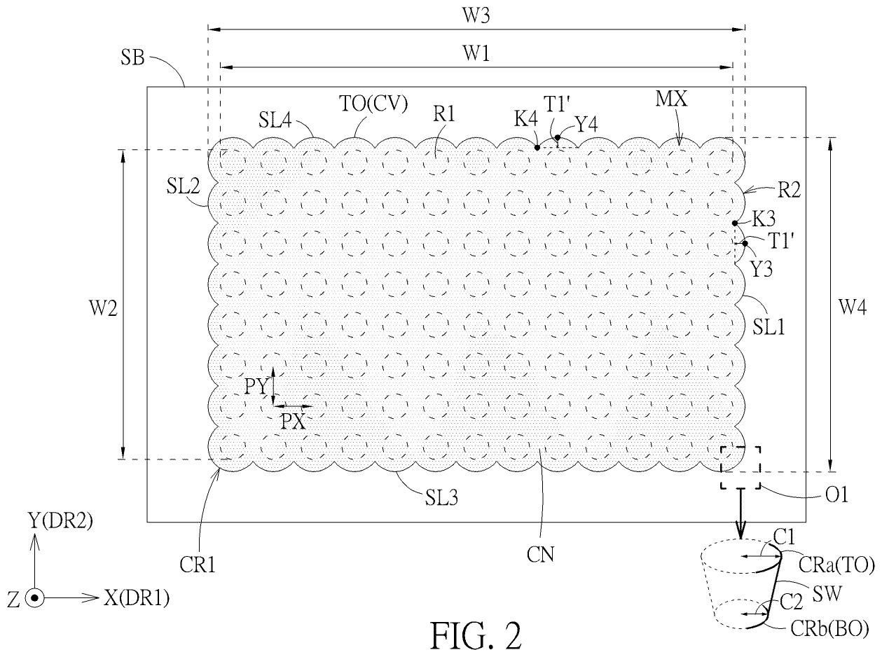

As shown in FIG. 2, in the top view of the electronic device ED, the first concaves R1 included in the bottom of the cavity CV may be arranged in a matrix MX. Specifically, the first concaves R1 may be arranged along a first direction DR1 and a second direction DR2 respectively, wherein the first direction DR1 is not parallel to the second direction DR2. In this embodiment, the first direction DR1 may be the direction X, and the second direction DR2 may be the direction Y. In the matrix MX formed by the first concaves R1, the number of the first concaves R1 in a row arranged along the first direction DR1 may be different from the number of the first concaves R1 in a column arranged along the second direction DR2. Specifically, the number of the first concaves R1 in a row arranged along the first direction DR1 may be greater than or equal to the number of the first concaves R1 in a column arranged along the second direction DR2. In such condition, the matrix MX may have a length W1 along the first direction DR1 and a length W2 along the second direction DR2, wherein the length W1 may be greater than the length W2. The length W1 may be defined as the maximum distance between outer edges of two first concaves R1 respectively located at the leftmost side and the rightmost side of a row of first concaves R1 arranged along the first direction DR1. The length W2 may be defined as the maximum distance between outer edges of two first concaves R1 respectively located at the uppermost side and the lowermost side of a column of first concaves R1 arranged along the second direction DR2. In some embodiments, the length W1 may be the same as the length W2.

The cavity CV may have a length W3 in the first direction DR1 and a length W4 in the second direction DR2, wherein the length W3 may be greater than the length W4. The length W3 may be defined as the maximum length of the profile of the top of the cavity CV in the first direction DR1 in the top view of the electronic device ED. The length W4 may be defined as the maximum length of the profile of the top of the cavity CV in the second direction DR2 in the top view of the electronic device ED. For example, the length W3 and the length W4 may respectively be the lengths of the top profile TO of the cavity CV in the first direction DR1 and the second direction DR2. The length W3 may range from 1500 μm to 2500 μm (1500 μm≤W3≤2500 μm), and the length W4 may range from 500 μm to 1500 μm (500 μm≤W4≤1500 μm). In an embodiment, the length W3 may be 2000 μm, and the length W4 may be 1000 μm. In some embodiments, the length W3 and the length W4 may be the same.

The first concaves R1 may have a pitch PX in the first direction DR1 and a pitch PY in the second direction DR2, wherein the pitch PX may be greater than the pitch PY. The pitch PX may be a pitch between two adjacent first concaves R1 in the first direction DR1, and the pitch PY may be a pitch between two adjacent first concaves R1 in the second direction DR2. In other words, the pitch of the first concaves R1 in a direction where the matrix MX has a larger length may be greater than the pitch of the first concaves R1 in another direction where the matrix MX has a smaller length. The pitch PX may be defined as the distance between the same relative positions of two adjacent first concaves R1 arranged along the first direction DR1. For example, in the top view of the electronic device ED, the pitch PX may be a distance between centers of two adjacent first concaves R1 arranged along the first direction DR1. The pitch PY may be defined as a distance between the same relative positions (for example, centers) of two adjacent first concaves R1 in the second direction DR2. The pitch PX may range from 7.5 μm to 12.5 μm (7.5 μm≤PX≤12.5 μm), and the pitch PY may range from 2.5 μm to 7.5 μm (2.5 μm≤PY≤7.5 μm). For example, the pitch PX may be 10 μm, and the pitch PY may be 5 μm. In some embodiments, the pitch PX and the pitch PY may be the same. In addition, the ratio of the length W3 to the pitch PX may be greater than or equal to 2(W3/PX≥2). In some embodiments, the ratio of the length W3 to the pitch PX may be greater than or equal to 10, 100 or 500(W3/PX≥10, 100, 500). The range of the ratio of the length W4 to the pitch PY may refer to the range of the ratio of the length W3 to the pitch PX mentioned above.

By making the bottom of the cavity CV include first concaves R1, the connection (provided by the connection layer CN) between the first electronic element EL1 and the cavity CV may be improved or the fixing effect of the connection layer CN on the first electronic element EL1 may be improved. In addition, by designing the range of the depth T1 and/or the range of the ratio of the depth T1 to the depth T2, the influence of the first concave R1 on the stability of the first electronic element EL1 may be reduced.

In the top view of the electronic device ED, the cavity CV includes at least one rounded corner. Specifically, FIG. 2 shows that the top profile TO of the cavity CV includes a corner CR1, and the corner CR1 may be rounded or have other non-sharp shapes. Although it is not shown, the top profile TO of the cavity CV may further include three other corners, wherein these corners may be rounded or have other non-sharp shapes. In addition, although it is not shown, the cavity CV may have a bottom profile BO, wherein the bottom profile BO may also include rounded corners. A radius of curvature of a rounded corner at the top of the cavity CV may be greater than a radius of curvature of another rounded corner at the bottom of the cavity CV and corresponding to the rounded corner. This design, with a larger radius at the top, facilitates the entry of the first electronic element EL1 during assembly, while the smaller radius at the bottom provides a more defined placement area, reducing stress concentration. “The rounded corner at the top (or bottom) of the cavity CV” described herein may be the rounded corner of the top profile TO (or bottom profile BO) of the cavity CV in the top view of the electronic device ED. In addition, “a rounded corner at the top of the cavity CV and another rounded corner at the bottom of the cavity CV and corresponding to the rounded corner” described above may be two rounded corners respectively in the top profile TO and the bottom profile BO of the cavity CV and located at the same side (or the same corner). FIG. 2 shows a partial enlarged view of a portion O1 of the cavity CV. At the top of the cavity CV, the cavity CV (or the top profile TO) includes a first rounded corner CRa, and at the bottom of the cavity CV, the cavity CV (or the bottom profile BO) includes a second rounded corner CRb corresponding to the first rounded corner CRa, wherein a radius of curvature C1 of the first rounded corner CRa may be greater than a radius of curvature C2 of the second rounded corner CRb.

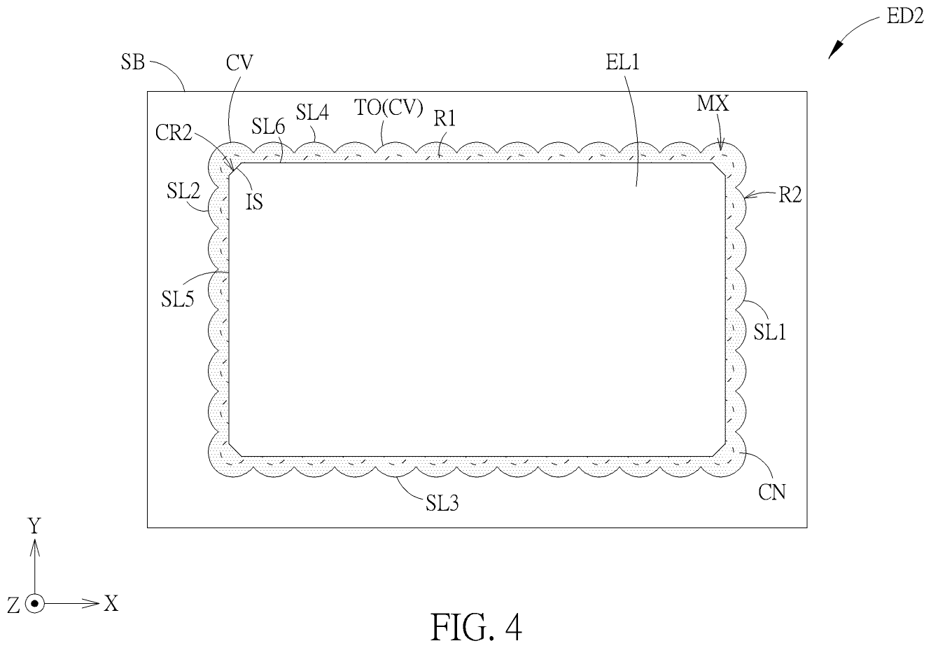

The side of the cavity CV of the electronic device ED may further include second concaves R2. The second concaves R2 may be located at the sidewall SW of the cavity CV. The second concaves R2 may be formed by removing a portion of the substrate SB at the sidewall SW. Although it is not shown, the second concave R2 may be a strip-shaped channel extending along the sidewall SW. A portion of the connection layer CN may be filled into the second concaves R2, thereby being disposed between the second concaves R2 and the first electronic element EL1 (shown in FIG. 4). In the top view of the electronic device ED, the side of the top profile TO of the cavity CV may be curved or have other non-linear shape due to the second concaves R2. For example, a side SL1 of the top profile TO of the cavity CV includes a wavy shape. It should be noted that the four sides of the cavity CV may all include the second concaves R2. In such condition, sides SL2, SL3 and SL4 of the top profile TO of the cavity CV may all have a wavy shape. In some embodiments, at least one side surface of the cavity CV may not include the second concave R2. Although it is not shown, the sides of the bottom profile BO of the cavity CV may also be curved or have other non-linear shapes due to the second concaves R2.

One of the second concaves R2 may have a depth T1′, wherein the depth T1′ may be defined in the top view of the electronic device ED. Specifically, the depth T1′ may be the maximum depth of the second concave R2 measured in a direction perpendicular to the normal direction of the electronic device ED. For example, the depth T1′ of a second concave R2 may be the distance between the valley Y3 of the top profile TO and the peak K3 in the direction X. Or, another depth T1′ of the second concave R2 may be the distance between the valley Y4 and the peak K4 of the top profile TO in the direction Y. It should be noted that the depth T1′ may also be measured from the bottom profile BO. The depth T1′ of one of the second recesses R2, measured in a direction parallel to the first surface S1, may be less than the depth T1 of one of the first recesses R1, measured in a direction normal to the first surface S1. Through the above-mentioned designs, the strength of connection (provided by the connection layer CN) between the first electronic element EL1 and the cavity CV may be improved.

Back to FIG. 1, the electronic device ED may further include a first circuit layer CL1 disposed on the first surface S1 of the substrate SB. For example, the first circuit layer CL1 includes an insulating layer I1, an insulating layer I2, a conductive layer M1, and a conductive layer M2. The insulating layer I1 is located on the first surface S1, and the insulating layer I2 is located on the insulating layer I1. The conductive layer M1 is located on the insulating layer I1, and the conductive layer M2 is located on the insulating layer I2. The insulating layer in the first circuit layer CL1 that is closest to the first surface S1 of the substrate SB may be partially disposed in the cavity CV. For example, the insulating layer I1 may be partially filled in the cavity CV and contact the connection layer CN. The first circuit layer CL1 may be used to electrically connect the first electronic element EL1 to other electronic elements of the electronic device ED, such as the second electronic element EL2 and the third electronic element EL3 mentioned below.

The electronic device ED may further include a second electronic element EL2 and a third electronic element EL3 disposed on the first surface S1 of the substrate SB. The second electronic element EL2 and the third electronic element EL3 may be disposed on the first circuit layer CL1. The first circuit layer CL1 may be configured to electrically connect the first electronic element EL1 and the second electronic element EL2 and electrically connect the first electronic element EL1 and the third electronic element EL3. Specifically, the first electronic element EL1 includes conductive pads BP1 (only one conductive pad BP1 is shown) located at a side opposite to the bottom surface BS1, and the conductive layer M1 in the first circuit layer CL1 may contact at least one conductive pad BP1 through a via in the insulating layer I1, thereby electrically connecting the conductive layer M1 to the first electronic element EL1. The conductive layer M2 may contact the conductive layer M1 through a via in the insulating layer I2, thereby being electrically connected to the conductive layer M1. The electronic device ED may further include solders SD1 (only one solder SD1 is shown) disposed between the first circuit layer CL1 and the second electronic element EL2, wherein the solders SD1 may be disposed corresponding to the conductive layer M2. The conductive layer M2 may be bonded to the conductive pads BP2 of the second electronic element EL2 through at least one solder SD1, thereby electrically connecting the first circuit layer CL1 and the second electronic element EL2. The electronic device ED may further include solders SD2 (only one solder SD2 is shown) disposed between the first circuit layer CL1 and the third electronic element EL3 and corresponding to the conductive layer M2, wherein the conductive layer M2 may be bonded to the conductive pads BP3 of the third electronic element EL3 through at least one solder SD2, thereby electrically connecting the first circuit layer CL1 and the third electronic element EL3. In some embodiments, the first circuit layer CL1 may be electrically connected to the second electronic element EL2 and the third electronic element EL3 through a hybrid bonding technique. In such condition, the electronic device ED may not include the solder SD1 and the solder SD2. Through the above-mentioned design, the first electronic element EL1 may be electrically connected between the second electronic element EL2 and the third electronic element EL3, and the second electronic element EL2 may be electrically connected to the third electronic element EL3 through the first circuit layer CL1 and the first electronic element EL1. The second electronic element EL2 and the third electronic element EL3 include system on chip (SoC), central processing unit (CPU), graphics processing unit (GPU), memory, logic die, other suitable electronic elements or combinations thereof. The first electronic element EL1 includes die, semiconductor die, integrated circuit (IC), chip, and the like. The first electronic element EL1 includes a bridge die or a bridge connector. In this case, the first electronic element EL1 may serve as a bridge element between the second electronic element EL2 and the third electronic element EL3 and may electrically connect the second electronic element EL2 and the third electronic element EL3.

The electronic device ED may further include a filling layer FL disposed on the first circuit layer CL1. The filling layer FL may be disposed between the first circuit layer CL1 and the second electronic element EL2 and between the first circuit layer CL1 and the third electronic element EL3, and the filling layer FL may surround the solders SD1 between the first circuit layer CL1 and the second electronic element EL2 and the solders SD2 between the first circuit layer CL1 and the third electronic element EL3. A portion of the filling layer FL may further be disposed between the second electronic element EL2 and the third electronic element EL3. The filling layer FL may provide protection for the electrical connection paths of the electronic device ED. The filling layer FL includes any suitable insulating material, such as epoxy resin or acrylic resin.

The electronic device ED may further include a second circuit layer CL2 disposed on the second surface S2 of the substrate SB. For example, the second circuit layer CL2 includes an insulating layer I3 and a conductive layer M3, wherein the insulating layer I3 is disposed on the second surface S2 of the substrate SB, and the conductive layer M3 is disposed on the insulating layer I3.

The first circuit layer CL1 may be electrically connected to the second circuit layer CL2 through a first conductive via CON1 in the substrate SB. The “conductive via” described herein may be a conductive element disposed in a via of a layer. In detail, the substrate SB includes a via V1 and a conductive element CE1 disposed in the via V1, wherein the conductive element CE1 may serve as the first conductive via CON1. The via V1 may penetrate the substrate SB, that is, the conductive via penetrating the substrate SB may be regarded as the first conductive via CON1. It should be noted that when the substrate SB is etched to form the via V1, the etching degree at the surfaces (such as the first surface S1 and the second surface S2) of the substrate SB may be greater than the etching degree at the center of the substrate SB. Therefore, the via V1 may be hourglass-shaped. An end E1 of the conductive element CE1 disposed in the via V1 may be substantially aligned with the first surface S1, and the conductive layer (such as the conductive layer M1) in the first circuit layer CL1 may contact the end E1 of the conductive element CE1 through a hole (not shown) in the insulating layer I1, such that the first circuit layer CL1 is electrically connected to the conductive element CE1. In addition, an end E2 of the conductive element CE1 disposed in the via V1 may be substantially aligned with the second surface S2, and the conductive layer (such as the conductive layer M3) in the second circuit layer CL2 may contact the end E2 of the conductive element CE1 through a hole (not shown) in the insulating layer I3, such that the second circuit layer CL2 is electrically connected to the conductive element CE1. Therefore, the first circuit layer CL1 may be electrically connected to the second circuit layer CL2 through the first conductive via CON1. In this case, the second electronic element EL2 may be electrically connected to the second circuit layer CL2 through at least one solder SD1, the first circuit layer CL1 and at least one first conductive via CON1, and the third electronic element EL3 may be electrically connected to the second circuit layer CL2 through at least one solder SD2, the first circuit layer CL1 and at least one first conductive via CON1.

A layer L1 may further be disposed in the via V1, wherein the layer L1 may be located between the substrate SB and the conductive element CE1. In some embodiments, the layer L1 may be a buffer layer. In some embodiments, the layer L1 may be a seed layer for assisting the disposition of the conductive element CE1. In some embodiments, the layer L1 may be a composite layer including a buffer layer and a seed layer. In this case, the buffer layer may be disposed between the substrate SB and the seed layer.

The first circuit layer CL1 may further be electrically connected to the second circuit layer CL2 through the first conductive via CON1′ in the substrate SB and the second conductive via CON2 in the first electronic element EL1. In detail, the substrate SB includes a via V2 and a conductive element CE2 disposed in the via V2, wherein the conductive element CE2 may serve as the first conductive via CON1′. In the normal direction of the electronic device ED, the via V2 may overlap the cavity CV. That is, the conductive via corresponding to the cavity CV may be regarded as the first conductive via CON1′. The via V2 may extend from the second surface S2 of the substrate SB and protrude from the bottom surface BS of the cavity CV to expose the bottom surface BS1 of the first electronic element EL1. The via V2 may be formed by removing a portion of the substrate SB corresponding to the cavity CV. In this case, the via V2 may further be formed by removing a portion of the connection layer CN located between the first electronic element EL1 and the first recess R1. The first electronic element EL1 includes conductive pads BP4 located at the side where the bottom surface BS1 is located, and the via V2 may expose at least one conductive pad BP4. In this case, an end E3 of the conductive element CE2 disposed in the via V2 may contact the conductive pad BP4, thereby electrically connecting the conductive element CE2 to the conductive pad BP4. In addition, another end E4 of the conductive element CE2 disposed in the via V2 may be substantially aligned with the second surface S2, and the conductive layer (such as the conductive layer M3) in the second circuit layer CL2 may contact the end E4 of the conductive element CE2 through a hole (not shown) in the insulating layer I3, thereby electrically connecting the second circuit layer CL2 to the conductive element CE2. In some embodiments, the layer L1 may further be disposed in the via V2. In this case, the layer L1 disposed in the via V2 may contact the connection layer CN.

The first electronic element EL1 includes a via V3 and a conductive element CE3 disposed in the via V3, wherein the conductive element CE3 may serve as the second conductive via CON2. The via V3 may connect one of the conductive pads BP1 and one of the conductive pads BP4. In this case, the conductive element CE3 disposed in the via V3 may be electrically connected between the conductive pad BP4 and the conductive pad BP1. The conductive layer M1 in the first circuit layer CL1 may contact the conductive pad BP1 through a hole in the insulating layer I1, thereby being electrically connected to the conductive pad BP1. Through the above-mentioned designs, the first circuit layer CL1 may be electrically connected to the second circuit layer CL2 through the second conductive via CON2 and the first conductive via CON1′. In some embodiments, the layer L1 may further be disposed in the via V3. In this case, the second electronic element EL2 may be electrically connected to the second circuit layer CL2 through at least one solder SD1, the first circuit layer CL1, at least one second conductive via CON2, and at least one first conductive via CON1′, and the third electronic element EL3 may be electrically connected to the second circuit layer CL2 through at least one solder SD2, the first circuit layer CL1, at least one second conductive via CON2, and at least one first conductive via CON1′.

The electronic device ED may further include an electronic element EL disposed at a side of the second circuit layer CL2 opposite to the substrate SB. The second circuit layer CL2 may be electrically connected to the electronic element EL. Specifically, the electronic device ED may further include solders SD3 disposed corresponding to the conductive layer M3 of the second circuit layer CL2, and the solders SD3 may be used to bond the second circuit layer CL2 to the electronic element EL. Therefore, the first electronic element EL1, the second electronic element EL2 and/or the third electronic element EL3 may be electrically connected to the electronic element EL through the first circuit layer CL1, the conductive via in the substrate SB and/or the second circuit layer CL2. The electronic element EL may for example include a printed circuit board (PCB), a flexible printed circuit board (FPCB), other suitable elements or combinations thereof.

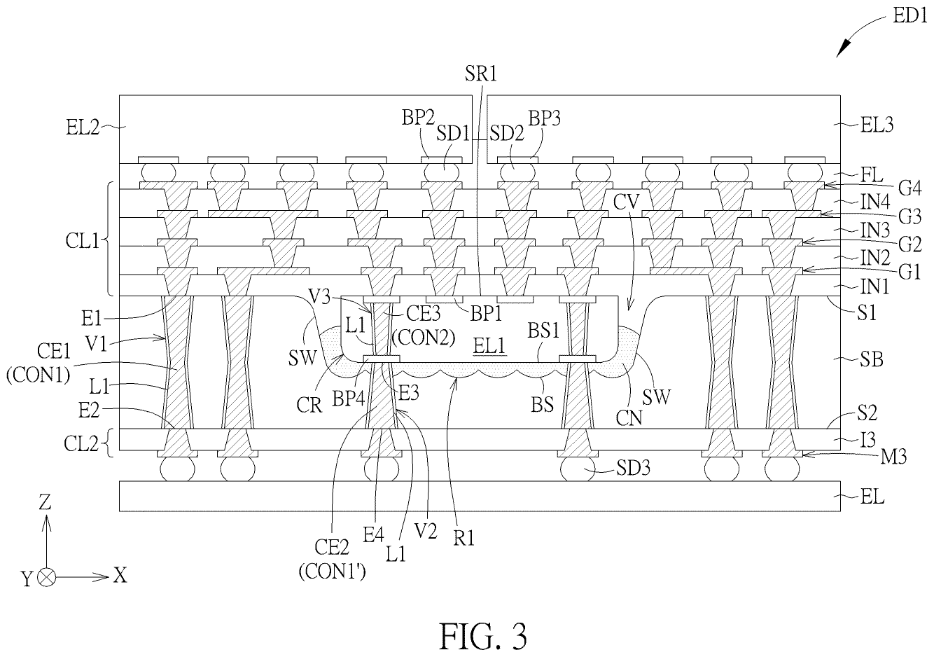

As shown in FIG. 3, the first circuit layer CL1 of the electronic device ED1 includes a redistribution layer (RDL). Specifically, as shown in FIG. 3, the first circuit layer CL1 includes an insulating layer IN1, an insulating layer IN2, an insulating layer IN3, an insulating layer IN4, a conductive layer G1, a conductive layer G2, a conductive layer G3, and a conductive layer G4. The insulating layer IN1 may be located on the substrate SB, and the conductive layer G1 may be located on the insulating layer IN1. The insulating layer IN2 may be located on the insulating layer IN1 and cover the conductive layer G1. The conductive layer G2 may be located on the insulating layer IN2. The insulating layer IN3 may be located on the insulating layer IN2 and cover the conductive layer G2. The conductive layer G3 may be located on the insulating layer IN3. The insulating layer IN4 may be located on the insulating layer IN3 and cover the conductive layer G3. The conductive layer G4 may be located on the insulating layer IN4. When a signal is transmitted between the first electronic element EL1 and the second electronic element EL2 and/or between the first electronic element EL1 and the third electronic element EL3, the position where the signal enters the first circuit layer CL1 and the position where the signal leaves the first circuit layer CL1 may not correspond to each other. Similarly, when transmitting signals between the second electronic element EL2 (or the third electronic element EL3) and the first conductive via CON1 (or the second conductive via CON2), the position where the signal enters the first circuit layer CL1 and the position where the signal leaves the first circuit layer CL1 may not correspond to each other. It should be noted that the second circuit layer CL2 includes the redistribution layer in some embodiments.

As shown in FIG. 4, in a top view of the electronic device ED2, the first electronic element EL1 disposed in the cavity CV of the substrate SB includes at least one chamfered corner. Specifically, in the top view of the first electronic element EL1, the profile of the first electronic element EL1 includes a corner CR2, wherein the corner CR2 may not have a sharp-angle (such as a right angle or an acute angle) shape. In detail, the corner CR2 includes a bevel IS, wherein the bevel IS may be connected between the side SL5 and the side SL6 of the first electronic element EL1, and the included angles between the bevel IS and the side SL5 and between the bevel IS and the side SL6 may be obtuse angles. The first electronic element EL1 may further include other three corners, wherein these corners may be chamfered corners. In some embodiments, the bevel IS of the corner CR2 may be a curve or an arc. The connection layer CN may contact at least one chamfered corner of the first electronic element EL1. Specifically, although it is not shown, the electronic device ED2 includes a side surface having the bevel IS as a side, and the connection layer CN may contact at least a portion of the side surface. Therefore, the contact area between the first electronic element EL1 and the connection layer CN may increase, thereby improving the bonding capability of the connection layer CN or reducing the possibility of breaking of corners of the first electronic element EL1.

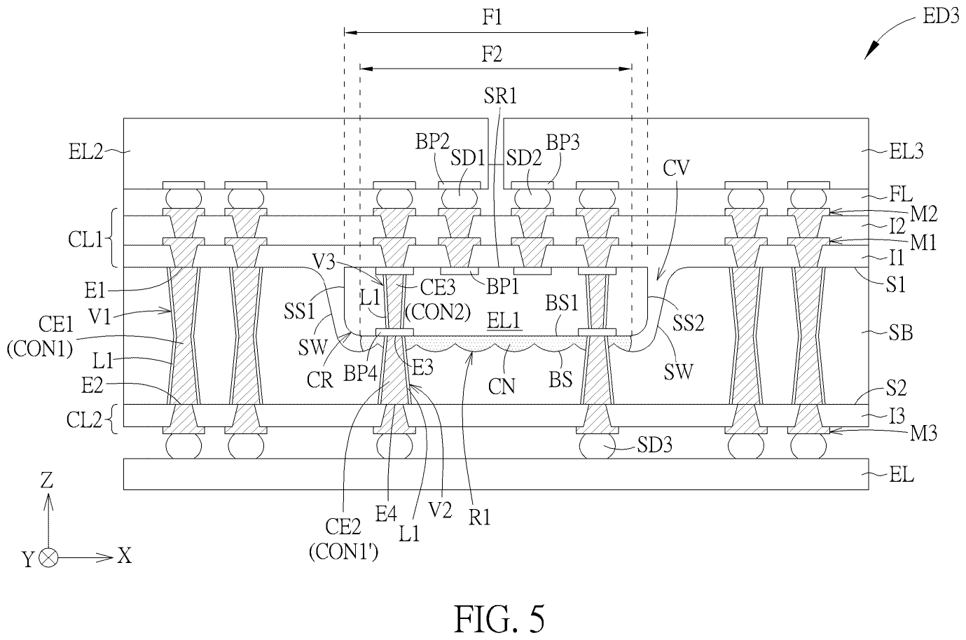

As shown in FIG. 5, in the electronic device ED3, the connection layer CN disposed in the cavity CV may not protrude from the first electronic element EL1. Specifically, in a cross-sectional view of the electronic device ED3, the left end and right end of the connection layer CN may not protrude beyond the side SS1 and the side SS2 of the first electronic element EL1, respectively. In other words, in the normal direction of the electronic device ED3, the disposition range of the connection layer CN falls within the disposition range of the first electronic element EL1. In this case, the width F2 of the connection layer CN may be less than the width F1 of the first electronic element EL1. In this embodiment, the width F2 may be less than the width F1 and greater than or equal to 50% of the width F1 (0.5F1≤F2<F1).

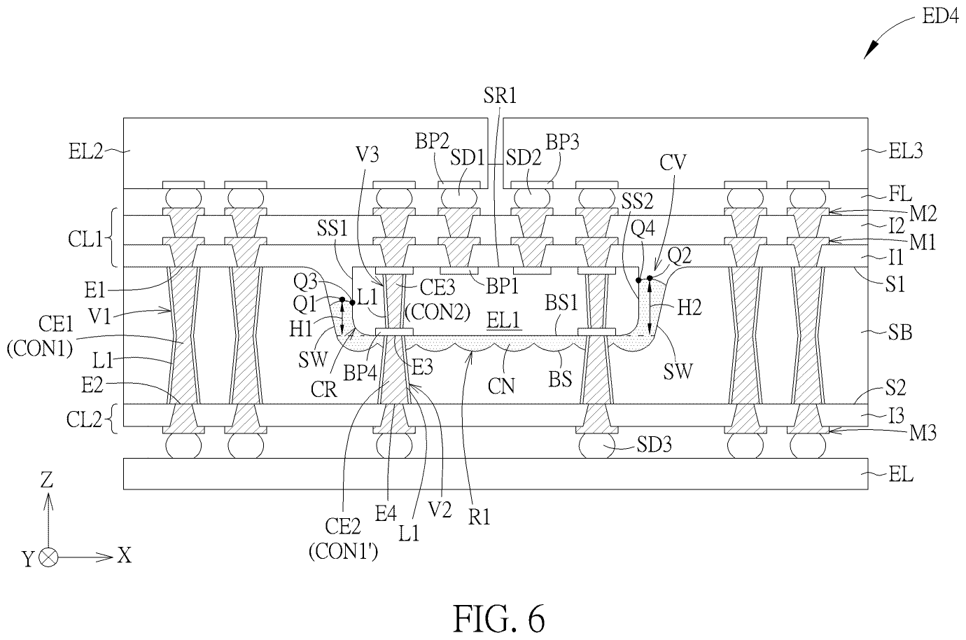

As shown in FIG. 6, in a cross-sectional view of the electronic device ED4, a height of a portion of the connection layer CN located between the left sidewall SW of the cavity CV and the first electronic element EL1 may be different from a height of a portion of the connection layer CN located between the right sidewall SW of the cavity CV and the first electronic element EL1. Specifically, a portion of the connection layer CN located between the left sidewall SW of the cavity CV and the first electronic element EL1 may have a height H1, wherein the height H1 may be defined as the distance between the highest point Q1 of the portion of the connection layer CN and the bottom surface BS1 of the first electronic element EL1 in the normal direction of the electronic device ED4; another portion of the connection layer CN located between the right sidewall SW of the cavity CV and the first electronic element EL1 may have a height H2, wherein the height H2 may be defined as the distance between the highest point Q2 of the another portion of the connection layer CN and the bottom surface BS1 of the first electronic element EL1 in the normal direction of the electronic device ED4, and the height H1 may be different from the height H2. For example, the height H2 may be greater than the height H1. Therefore, the contact point Q3 between the side SS1 and the connection layer CN may be lower than the contact point Q4 between the side SS2 and the connection layer CN. In some embodiments, the height H1 may be greater than the height H2.

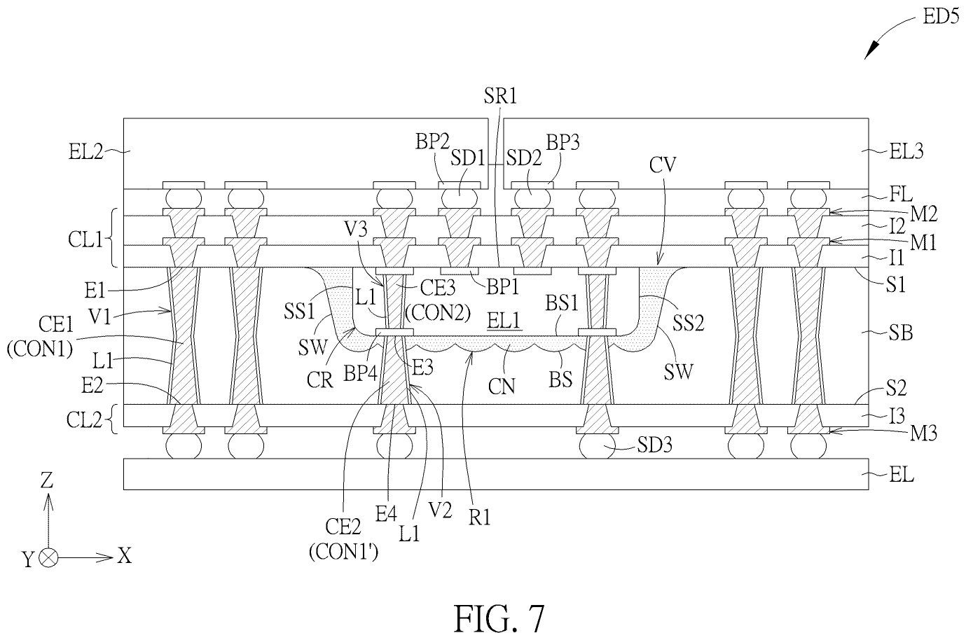

As shown in FIG. 7, in the electronic device ED5, after the first electronic element EL1 is disposed in the cavity CV, the connection layer CN may fill up the remaining space of the cavity CV. Specifically, the connection layer CN may completely cover the sidewall SW of the cavity CV, and the top surface of the connection layer CN may be substantially aligned with the first surface S1 of the substrate SB. In this case, the insulating layer I1 may not be filled into the cavity CV and may contact the top surface of the connection layer CN.

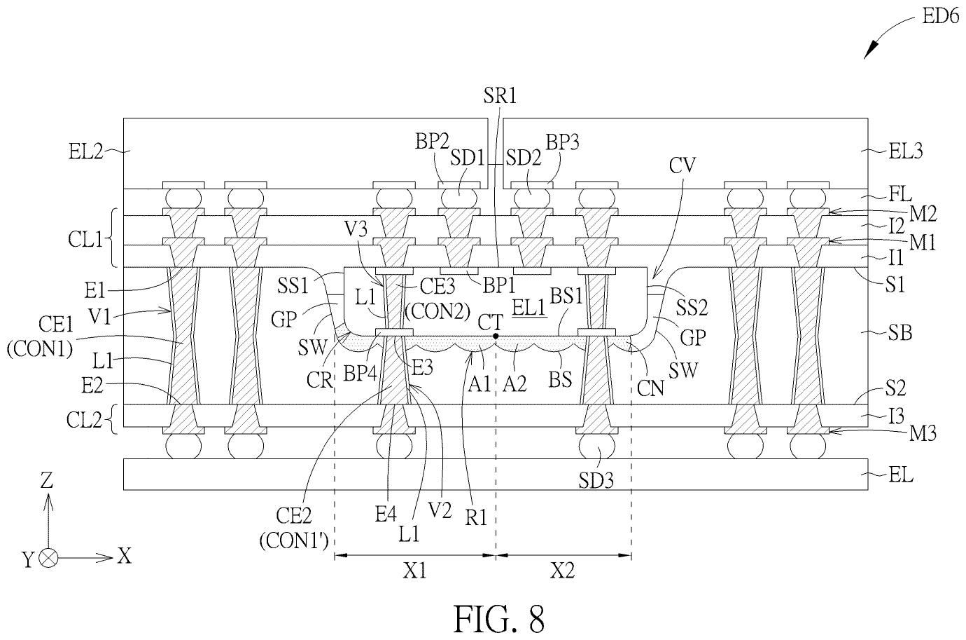

As shown in FIG. 8, in a cross-sectional view of the electronic device ED6, the portions of the connection layer CN respectively located at two sides of the center of the first electronic element EL1 may have different widths. Specifically, in a cross-sectional view of the electronic device ED6, the bottom surface BS1 of the first electronic element EL1 may have a center CT, and the connection layer CN includes a portion A1 located on the left side of the center CT and a portion A2 located on the right side of the center CT. The portion A1 of the connection layer CN may have a width X1, and the portion A2 of the connection layer CN may have a width X2, wherein the width X1 may be different from the width X2. The width X1 may for example be defined as the distance between the leftmost end of the portion A1 and the center CT in a cross-sectional view of the electronic device ED6 in a direction perpendicular to the normal direction of the electronic device ED6 (such as the direction X). The width X2 may for example be defined as the distance between the rightmost end of the portion A2 and the center CT in the cross-sectional view of the electronic device ED6 in a direction perpendicular to the normal direction of the electronic device ED6 (such as the direction X). In this embodiment, the width X1 may be greater than the width X2. In some embodiments, the width X2 may be greater than the width X1. The insulating layer I1 of the first circuit layer CL1 may fill into the cavity CV but may not contact the connection layer CN. Specifically, the electronic device ED6 may further include a gap GP in the cavity CV, wherein the gap GP may be located between the insulating layer I1 and the connection layer CN. The gap GP may include air. In other embodiments, the gap GP may be filled with any suitable material.

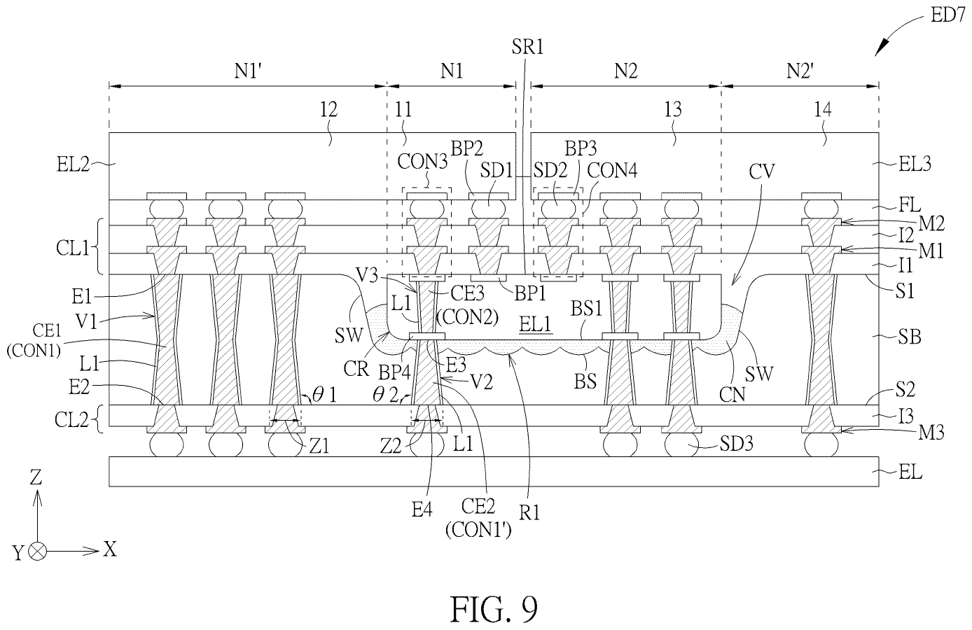

As shown in FIG. 9, in a cross-sectional view of the electronic device ED7, the second electronic element EL2 includes a portion 11 overlapping the first electronic element EL1 and a portion 12 not overlapping the first electronic element EL1, and the third electronic element EL3 includes a portion 13 overlapping the first electronic element EL1 and a portion 14 not overlapping the first electronic element EL1. The portion 11 may have a first width N1, and the portion 13 may have a second width N2, wherein the first width N1 may be different from the second width N2. In addition, the portion 12 may have a third width N1′, and the portion 14 may have a fourth width N2′, wherein the third width N1′ may be different from the fourth width N2′. Moreover, the bottom width of the first electronic element EL1 may be less than the bottom width of the second electronic element EL2 and the bottom width of the third electronic element EL3, and the bottom width of the second electronic element EL2 may be different from the bottom width of the third electronic element EL3. The bottom width of the first electronic element EL1 may be the same as the width F1 mentioned above, the bottom width of the second electronic element EL2 may be sum of the first width N1 and the third width N1′, and the bottom width of the third electronic element EL3 may be sum of the second width N2 and the fourth width N2′.

In this embodiment, the number of conductive vias electrically connected between the first electronic element EL1 and the second electronic element EL2 may be different from the number of conductive vias electrically connected between the first electronic element EL1 and the third electronic element EL3. Specifically, in the first circuit layer CL1, at least one electrical connection path between the second electronic element EL2 (or the third electronic element EL3) and the first electronic element EL1 may be formed by filling the conductive layer into the vias of the insulating layer. In this case, in one of the electrical connection paths between the second electronic element EL2 (or the third electronic element EL3) and the first electronic element EL1, the conductive layer filled into the via of the insulating layer may be regarded as a conductive via electrically connected between the first electronic element EL1 and the second electronic element EL2 (or the third electronic element EL3) mentioned above. As shown in FIG. 9, the electronic device ED7 includes a conductive via CON3 electrically connected between the first electronic element EL1 and the second electronic element EL2 and a conductive via CON4 electrically connected between the first electronic element EL1 and the third electronic element EL3, wherein the conductive via CON3 and the conductive via CON4 may respectively include the conductive layer M1 filled into the via of the insulating layer I1 and the conductive layer M2 filled into the via of the insulating layer I2. In this embodiment, the electronic device ED7 includes two conductive vias electrically connected between the first electronic element EL1 and the second electronic element EL2 and three conductive vias electrically connected between the first electronic element EL1 and the third electronic element EL3. In addition, the number of the conductive vias electrically connected between the second electronic element EL2 and the substrate SB (or the conductive via of the substrate SB) may be different from the number of the conductive vias electrically connected between the third electronic element EL3 and the substrate SB. As shown in FIG. 9, the electronic device ED7 includes three conductive vias electrically connected between the second electronic element EL2 and the substrate SB and one conductive via electrically connected between the third electronic element EL3 and the substrate SB.

In a cross-sectional view of the electronic device ED7, the profile of the vias in the substrate SB that do not correspond to the cavity CV (for example, the via V1) may be different from the profile of the vias in the substrate SB that correspond to the cavity CV (for example, the via V2). Specifically, in a cross-sectional view of the electronic device ED7, the via V1 includes a funnel-shaped profile, and the via V2 includes a trapezoidal profile. This difference in profile may result from different etching processes or boundary conditions; for example, the formation of via V2 is influenced by the presence of the cavity CV and the connection layer CN.

In a cross-sectional view of the electronic device ED7, the via in the substrate SB that does not correspond to the cavity CV (for example, the via V1) may have a width Z1 at the second surface S2, and the via in the substrate SB that corresponds to the cavity CV (for example, the via V2) may have a width Z2 at the second surface S2, wherein the width Z1 may be different from the width Z2. The width Z2 may be less than the width Z1. An included angle θ1 may be included between the via (for example, the via V1) in the substrate SB that does not correspond to the cavity CV and the second surface S2, and an included angle θ2 may be included between the via (for example, the via V2) in the substrate SB that corresponds to the cavity CV and the second surface S2, wherein the included angle θ1 may be different from the included angle θ2.

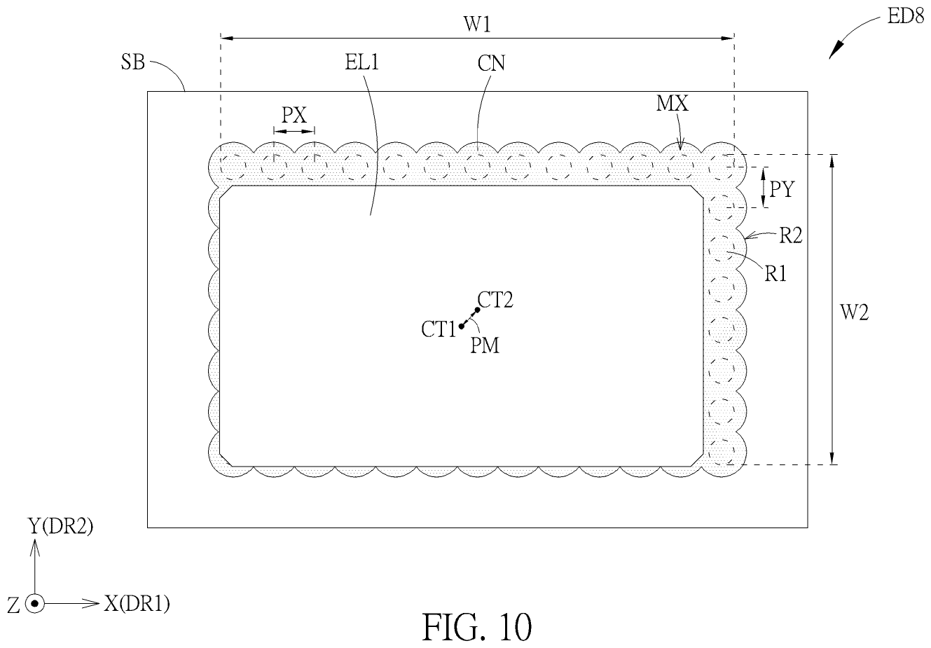

As shown in FIG. 10, in a top view of the electronic device ED8, the first electronic element EL1 may have a center CT1, and the cavity CV may have a center CT2, wherein the center CT1 may be offset from the center CT2. The center CT1 may be defined as the geometric center of the top view profile of the first electronic element EL1, and the center CT2 may be defined as the geometric center of the top view profile of the cavity CV. In a top view of the electronic device ED8, a distance PM may be included between the center CT1 and the center CT2, wherein the distance PM may be less than 0.5 times the length W1 of the matrix MX. In some embodiments, the distance PM may be less than 0.5 times the length W2 of the matrix MX. In some embodiments, the distance PM may be less than 0.4 times the length W1 (or the length W2) (PM<0.4W1, or PM<0.4W2). In some embodiments, the distance PM may be less than 0.3 times the length W1 (or the length W2) (PM<0.3W1, or PM<0.3W2).

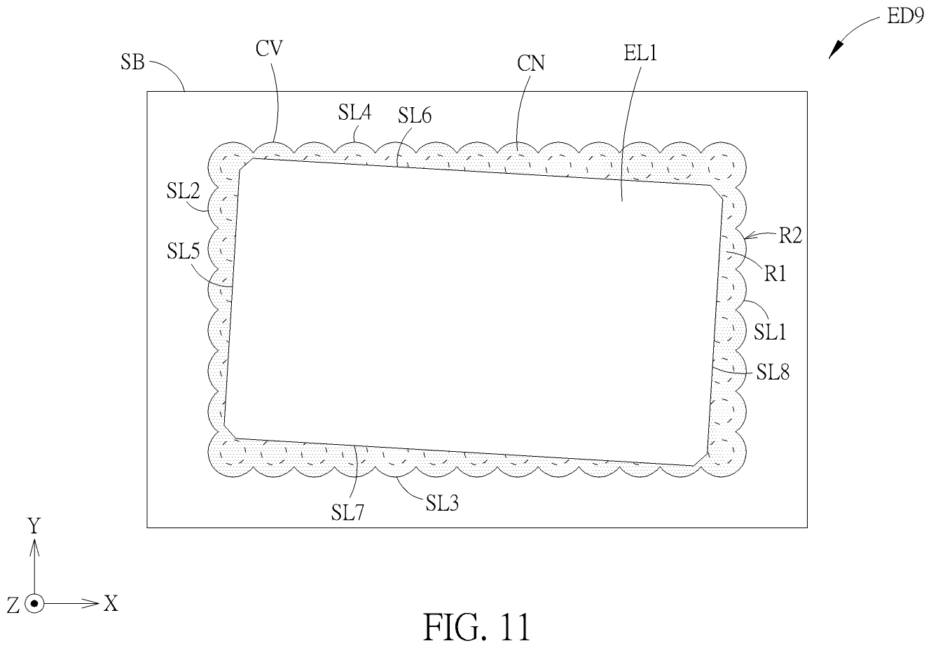

As shown in FIG. 11, in a top view of the electronic device ED9, the first electronic element EL1 may be twisted relative to the cavity CV. In this case, a side of the first electronic element EL1 and a side of the cavity CV adjacent to the side may have different extending directions. For example, the first electronic element EL1 may have a side SL5, a side SL6, a side SL7 and a side SL8, wherein the extending direction of the side SL5 may not be parallel to the extending direction of the side SL2 of the cavity CV, the extending direction of the side SL6 may not be parallel to the extending direction of the side SL4 of the cavity CV, the extending direction of the side SL7 may not be parallel to the extending direction of the side SL3 of the cavity CV, and the extending direction of the side SL8 may not be parallel to the extending direction of the side SL1 of the cavity CV.

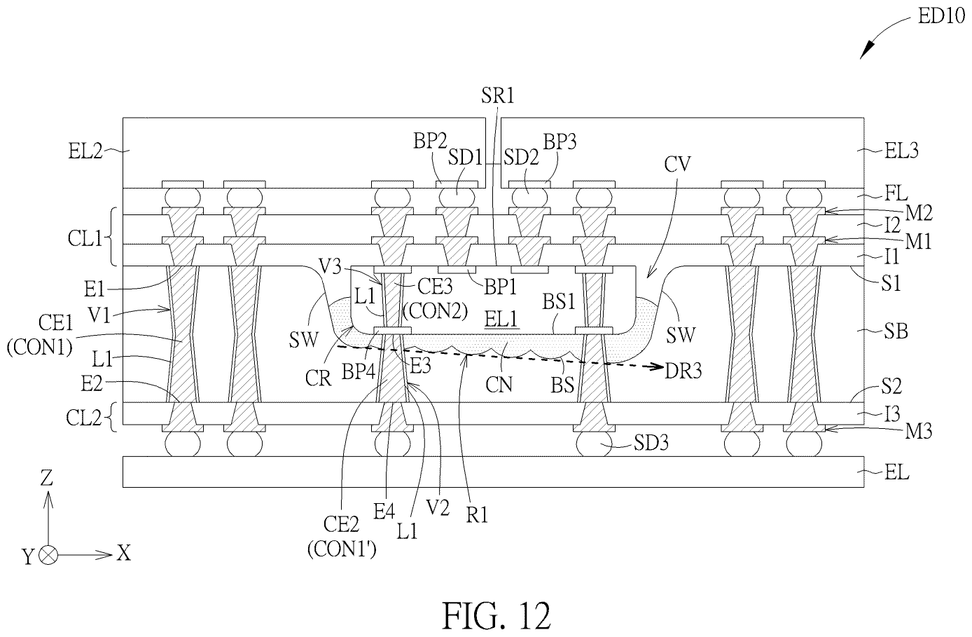

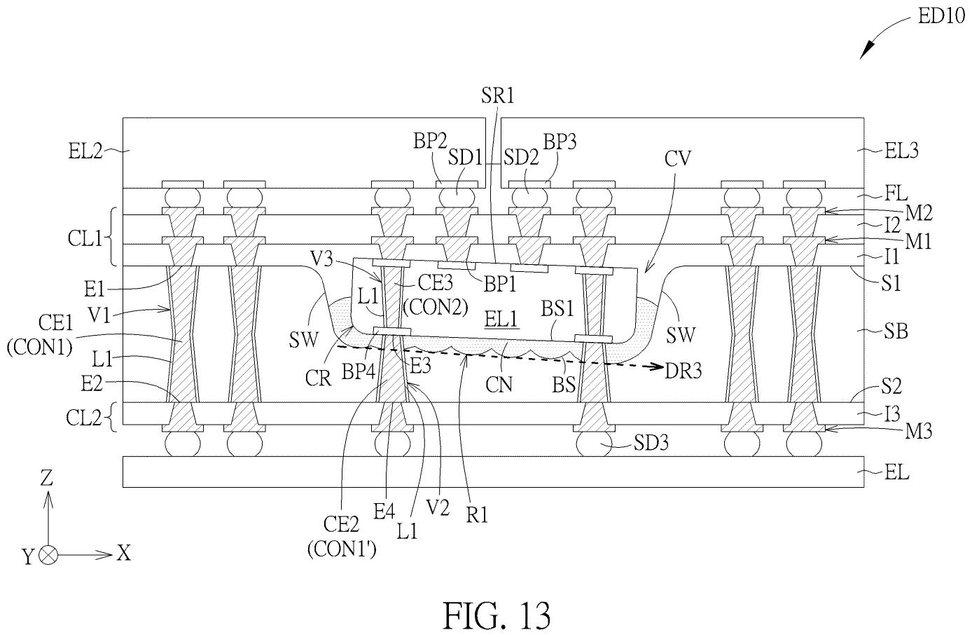

As shown in FIG. 12, in a cross-sectional view of the electronic device ED10, the bottom surface BS of the cavity CV may be inclined. For example, as shown in FIG. 12, the bottom surface BS of the cavity CV may have an extending direction DR3, wherein the extending direction DR3 may not be parallel to the direction X. The extending direction DR3 of the bottom surface BS may be defined as the extending direction of the line connecting the valleys (or relative low points) on the bottom surface BS. In addition, the first electronic element EL1 disposed in the cavity CV may not be tilted. Specifically, the bottom surface BS1 of the first electronic element EL1 may be substantially perpendicular to the normal direction of the electronic device ED10. In such condition, the bottom surface BS1 may not be parallel to the extending direction DR3. In addition, the distance (not labeled, the distance T3 mentioned above) between the bottom surface BS1 of the first electronic element EL1 and the bottom of the first recess R1 in the normal direction of the electronic device ED10 may gradually increase as approaching the sidewall SW of the cavity CV. In some embodiments, as shown in FIG. 13, the first electronic element EL1 may be tilted in a cross-sectional view of the electronic device ED10. For example, the bottom surface BS1 may be substantially parallel to the extending direction DR3.

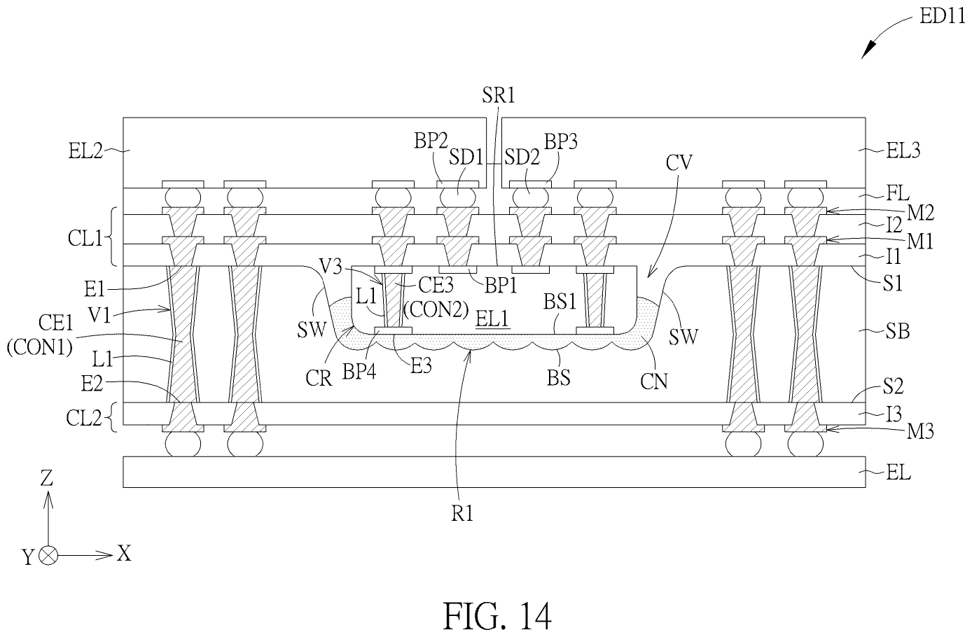

As shown in FIG. 14, the electronic device ED11 may not include the via corresponding to the cavity CV. Specifically, the electronic device ED11 may not include the via V2 protruding from the bottom surface BS of the cavity CV. In this case, the substrate SB may not include the first conductive via CON1′ shown in FIG. 1. In addition, the first electronic element EL1 may not include the conductive pad BP4. Moreover, the first electronic element EL1 may not include the second conductive via CON2. In this embodiment, the first circuit layer CL1 may for example be electrically connected to the second circuit layer CL2 through the first conductive via CON1 in the substrate SB.

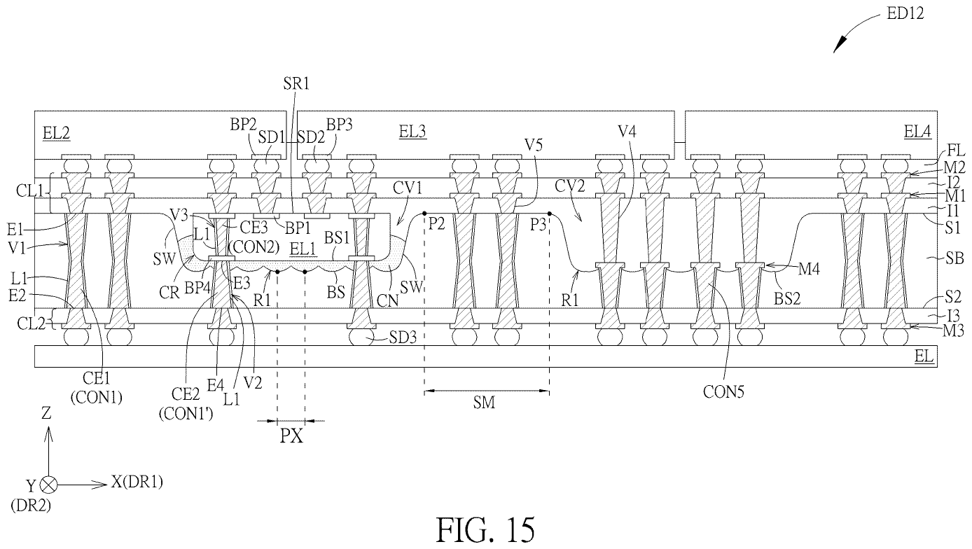

As shown in FIG. 15, the substrate SB of the electronic device ED12 includes cavities, wherein a portion of the cavities may not be provided with electronic element. For example, the substrate SB of the electronic device ED12 includes a cavity CV1 and a cavity CV2, wherein the first electronic element EL1 is disposed in the cavity CV1, and no electronic element is disposed in the cavity CV2. In this case, the connection layer CN may not be disposed in the cavity CV2. The electronic device ED12 may further include the conductive layer M4 disposed in a cavity (such as the cavity CV2) where no electronic element is disposed. Specifically, the conductive layer M4 may be disposed on the bottom surface BS2 of the cavity CV2. The conductive layer M4 may not be disposed corresponding to the first recesses R1 at the bottom of the cavity CV2. The insulating layer I1 in the first circuit layer CL1 may be filled into the cavity CV2 where no electronic element is provided and contact the bottom surface BS2 of the cavity CV2, wherein the insulating layer I1 includes a via V4, which may extend into the cavity CV2 and expose the conductive layer M4, and the conductive layer M1 may be filled into the via V4 and contact the conductive layer M4, thereby being electrically connected to the conductive layer M4. The substrate SB may further include a conductive via CON5 corresponding to the cavity CV2, wherein the conductive via CON5 may contact the conductive layer M4 to be electrically connected to the conductive layer M4. Therefore, the first circuit layer CL1 may be electrically connected to the conductive via CON5 corresponding to the cavity CV2, thereby being electrically connected to the second circuit layer CL2. In this case, the insulating layer I1 of the first circuit layer CL1 includes a via (such as the via V4) corresponding to the cavity CV2 and a via (such as the via V5) not corresponding to the cavity, wherein the height of the via V4 may be greater than the height of the via V5.

The electronic element disposed on the first circuit layer CL1 in the electronic device ED12 may cross multiple cavities. For example, the electronic device ED12 includes a second electronic element EL2, a third electronic element EL3 and a fourth electronic element EL4 disposed on the first circuit layer CL1, wherein the third electronic element EL3 may cross the cavity CV1 and the cavity CV2. “The third electronic element EL3 crosses the cavity CV1 and the cavity CV2” described herein may represent that the third electronic element EL3 may at least partially overlap the cavity CV1 and at least partially overlap the cavity CV2 in the normal direction of the electronic device ED12. Although it is not shown, the second electronic element EL2 may cross the cavity CV1 and other cavities (not shown) in the substrate SB, and the fourth electronic element EL4 may cross the cavity CV2 and other cavities (not shown) in the substrate SB.

In this embodiment, a distance SM may be included between two adjacent cavities in the substrate SB in the first direction DR1. The distance SM may be measured in a cross-sectional view (for example, FIG. 15) of the electronic device ED12 parallel to the first direction DR1 (the direction X). For example, the substrate SB includes a cavity CV1 and a cavity CV2 adjacent to each other, wherein a distance SM may be included between the sidewall SW of cavity CV1 adjacent to cavity CV2 and the sidewall SW of cavity CV2 adjacent to cavity CV1 in the first direction DR1. In detail, the upper end (or starting point) of the right sidewall SW of the cavity CV1 may correspond to a point P2 on the first surface S1, and the upper end (or starting point) of the left sidewall SW of the cavity CV2 may correspond to a point P3 on the first surface S1, and the distance SM may be defined as the distance between the point P2 and the point P3 in the first direction DR1. The definitions of the point P2 and the point P3 may refer to the definition of the point P1 in FIG. 1. The distance SM may be greater than 5 times the pitch PX of the first recesses R1 in the first direction DR1 (SM>5PX). In other words, the distance between two adjacent cavities in the substrate SB in an arrangement direction of the first recesses R1 may be greater than the pitch of the first recesses R1 in the arrangement direction. In some embodiments, the distance SM may be greater than 10 or 15 times the pitch PX of the first recesses R1 in the first direction DR1 (SM>10PX or 15PX). Although it is not shown, the distance between two adjacent cavities in the substrate SB in the second direction DR2 may be greater than 5 times the pitch (the pitch PY) of the first recesses R1 in the second direction DR2.

Although it is not shown in the figure, a dummy electronic element may be included in the cavity of the substrate SB. For example, in the electronic device ED12 shown in FIG. 15, the first electronic element EL1 in the cavity CV1 may be a dummy electronic element. In this case, the first electronic element EL1 may not be electrically connected to the first circuit layer CL1, the second circuit layer CL2, the second electronic element EL2, the third electronic element EL3, and the fourth electronic element EL4. For example, the conductive layer in the first circuit layer CL1 may not contact the first electronic element EL1, and the substrate SB may not include the conductive via corresponding to the cavity CV1. In some embodiments, the conductive layer in the first circuit layer CL1 may contact the top surface (the surface SR1) of the first electronic element EL1 through the vias in the insulating layer, but the top surface of the first electronic element EL1 may not include conductive pad or other conductive elements. In this case, the conductive layer in the first circuit layer CL1 that is filled into the via of the insulating layer and contacts the first electronic element EL1 may be regarded as a dummy conductive element or a dummy conductive via. In some embodiments, the substrate SB includes a first conductive via CON1′ corresponding to the cavity CV1 and contacting the bottom surface BS1 of the first electronic element EL1, but the bottom surface BS1 of the first electronic element EL1 may not include conductive pad or other conductive elements.

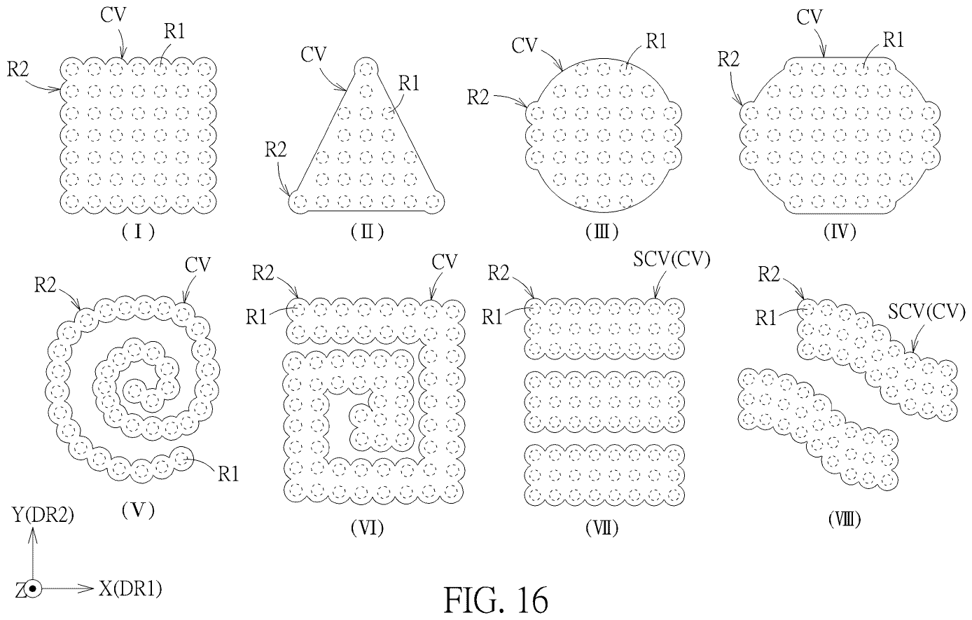

As shown in FIG. 16, in a top view of the electronic device, the top view profile of the cavity CV in the substrate may have any suitable shape. In some embodiments, as shown in the structure (I), the top view profile of the cavity CV may be rectangular. In some embodiments, as shown in the structure (II), the top view profile of the cavity CV may be triangular. In some embodiments, as shown in the structure (III), the top view profile of the cavity CV may be circular. In some embodiments, as shown in the structure (IV), the top view profile of the cavity CV may be elliptical. In some embodiments, as shown in the structure (V), the top view profile of the cavity CV may have a shape of a mosquito coil. In some embodiments, as shown in the structure (VI), the top view profile of the cavity CV may be spiral. In some embodiments, as shown in the structure (VII) and the structure (VIII), the cavity CV includes sub cavities SCV separated from each other, wherein the top view profile of the sub cavity SCV may be rectangular (as shown in structure (VII)), curved (as shown in structure (VIII)) or include other suitable shapes. In some embodiments, since the cavity CV may further include the second recesses R2, at least a portion of the top view profile of the cavity CV or the sub cavity SCV shown in the structure (I) to the structure (VIII) may be curved (for example, wavy). In some embodiments, as shown in the structure (I) to the structure (IV) and the structure (VII), the first recesses R1 may be arranged along the first direction DR1 and the second direction DR2, wherein the shape of the area enclosed by the outer edges of the outermost first recesses R1 may match the shape of the top view profile of the cavity CV. In some embodiments, as shown in the structure (V), the structure (VI) and the structure (VIII), the first recesses R1 may be arranged along the top view profile of the cavity CV or the sub cavity SCV, but not along the first direction DR1 and the second direction DR2 mentioned above.

In summary, an electronic device is provided by the present disclosure, wherein the substrate of the electronic device includes a cavity for disposing electronic element(s) and a connection layer connecting the electronic element(s) and the cavity. The bottom of the cavity includes first recesses. Therefore, the connection between the electronic element(s) and the cavity may be improved.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. An electronic device, comprising:
a substrate comprising a first surface and a second surface opposite to the first surface, wherein the first surface comprises a cavity, and a bottom of the cavity comprises a plurality of first concaves;
a first electronic element disposed in the cavity; and
a connection layer disposed in the cavity and contacting the first electronic element,
wherein at least a portion of the connection layer is disposed between the plurality of first concaves and the first electronic element.

2. The electronic device according to claim 1, wherein the at least a portion of the connection layer fills in the plurality of first concaves.

3. The electronic device according to claim 1, wherein a depth of one of the plurality of first concaves is ranged from 0.5 μm to 20 μm.

4. The electronic device according to claim 1, wherein a ratio of a depth of one of the plurality of first concaves to a depth of the cavity is ranged from 0.01 to 0.25.

5. The electronic device according to claim 1, wherein the plurality of first concaves are arranged in a matrix, a length of the matrix along a first direction is greater than a length of the matrix along a second direction, wherein a pitch of the plurality of first concaves in the first direction is greater than a pitch of the plurality of first concaves in the second direction.

6. The electronic device according to claim 1, wherein a distance between a bottom of the first electronic element and a bottom of one of the plurality of first concaves is greater than a depth of one of the plurality of first concaves.

7. The electronic device according to claim 1, wherein in a cross-sectional view of the electronic device, a width of the connection layer is greater than or equal to 50% of a width of the first electronic element.

8. The electronic device according to claim 1, wherein in a top view of the electronic device, the first electronic element comprises at least one chamfered corner.

9. The electronic device according to claim 8, wherein the connection layer is in contact with the at least one chamfered corner.

10. The electronic device according to claim 1, wherein a side of the cavity comprises a plurality of second concaves, and at least another portion of the connection layer is disposed between the plurality of second concaves and the first electronic element.

11. The electronic device according to claim 10, wherein a depth of one of the plurality of first concaves measured in a direction normal to the first surface is greater than a depth of one of the plurality of second concaves measured in a direction parallel to the first surface.

12. The electronic device according to claim 1, wherein in a top view of the electronic device, the cavity comprises at least one rounded corner.

13. The electronic device according to claim 1, wherein the cavity has a first rounded corner at a top of the cavity and a second rounded corner at a bottom of the cavity, and a radius of curvature of the first rounded corner is greater than a radius of curvature of the second rounded corner.

14. The electronic device according to claim 1, further comprising a second electronic element and a third electronic element disposed on the first surface, wherein the first electronic element electrically connects the second electronic element and the third electronic element.

15. The electronic device according to claim 14, wherein in a cross-sectional view of the electronic device, the second electronic element overlaps the first electronic element by a first width, the third electronic element overlaps the first electronic element by a second width, and the first width is different from the second width.

16. The electronic device according to claim 1, wherein in a top view of the electronic device, a center of the first electronic element is shifted away from a center of the cavity.

17. The electronic device according to claim 1, further comprising:
a first circuit layer disposed on the first surface;
a second electronic element disposed on the first surface; and
a third electronic element disposed on the first surface,
wherein the first circuit layer is configured to electrically connect the first electronic element and the second electronic element and electrically connect the first electronic element and the third electronic element.

18. The electronic device according to claim 17, further comprising a second circuit layer disposed on the second surface, wherein the first circuit layer is electrically connected to the second circuit layer through a first conductive via in the substrate.

19. The electronic device according to claim 18, wherein the first circuit layer is electrically connected to the second circuit layer through another first conductive via in the substrate and a second conductive via in the first electronic element.

20. The electronic device according to claim 18, wherein the substrate comprises glass.
